(19) United States
(12) Patent Application Publication
(10) Pub. No.: US 2024/0363737 A1
(43) Pub. Date: Oct. 31, 2024

(54) MANUFACTURING METHOD OF DISPLAY SUBSTRATE, DISPLAY SUBSTRATE AND DISPLAY DEVICE

(71) Applicants: HEFEI XINSHENG OPTOELECTRONICS TECHNOLOGY CO., LTD., Hefei (CN); BOE TECHNOLOGY GROUP CO., LTD., Beijing (CN)

(72) Inventors: Jun Liu, Beijing (CN); Luke Ding, Beijing (CN); Jingang Fang, Beijing (CN); Bin Zhou, Beijing (CN); Leilei Cheng, Beijing (CN); Wei Li, Beijing (CN)

(21) Appl. No.: 18/769,204

(22) Filed: Jul. 10, 2024

Related U.S. Application Data
(63) Continuation of application No. 17/449,607, filed on Sep. 30, 2021, now Pat. No. 12,062,711.
Application No. 17/449,607 is a continuation of application No. 15/983,055, filed on May 17, 2018, now abandoned.

(30) Foreign Application Priority Data
Nov. 23, 2017 (CN) 201711181291.9

(51) Int. Cl. H01L 29/66; H01L 21/027; H01L 21/311; H01L 21/3213; H01L 21/44; H01L 21/475; H01L 21/4757; H01L 21/4763; H01L 27/12; H01L 29/40; H01L 29/417; H01L 29/786

(52) U.S. Cl. CPC H01L 29/66969; H01L 21/0274; H01L 21/31116; H01L 21/31144; H01L 21/32139; H01L 21/44; H01L 21/475; H01L 21/47573; H01L 21/47635; H01L 27/1288; H01L 29/401; H01L 29/7869; H01L 29/41733; H01L 29/78633

(57) ABSTRACT

Provided are a manufacturing method of a display substrate, a display substrate, and a display device. The display substrate includes: a base substrate; and a top-gate type thin film transistor located on a side of the base substrate, the top-gate type thin film transistor comprises an active layer, a gate insulation layer and a gate electrode sequentially disposed in a direction away from the base substrate. A side surface of the gate insulation layer close to the gate electrode extends beyond an edge of the gate electrode in a direction parallel to the base substrate, and a side surface of the active layer close to the gate insulation layer extends beyond an edge of the gate insulation layer in the direction parallel to the base substrate.

### CROSS-REFERENCE TO RELATED APPLICATION

This application is a continuation of U.S. application Ser. No. 17/449,607 filed on Sep. 30, 2021, which is a continuation of U.S. application Ser. No. 15/983,055 filed on May 17, 2018, which in turn claims the priority benefit of Chinese Patent Application No. 201711181291.9 filed on Nov. 23, 2017 in the State Intellectual Property Office of China, the disclosures of which are incorporated herein by reference in entireties.

### BACKGROUND

### Technical Field

Embodiments of the present disclosure relate to the field of display technology, and in particular, to a manufacturing method of a display substrate, a display substrate, and a display device.

### Description of the Related Art

An Organic Light-Emitting Diode (OLED) display device has advantages such as thinness, lightness, wide viewing angle, active light emission, continuously adjustable light color, low cost, fast response speed, low energy consumption, low driving voltage, wide operating temperature range, simple production process, high luminous efficiency, flexible display and the like, therefore it is considered as a next-generation display technology with promising development.

### SUMMARY

In an aspect, a display substrate is provided, including: a base substrate; and a top-gate type thin film transistor located on a side of the base substrate, the top-gate type thin film transistor includes an active layer, a gate insulation layer and a gate electrode sequentially disposed in a direction away from the base substrate. A side surface of the gate insulation layer close to the gate electrode extends beyond an edge of the gate electrode in a direction parallel to the base substrate, and a side surface of the active layer close to the gate insulation layer extends beyond an edge of the gate insulation layer in the direction parallel to the base substrate.

According to the embodiments of the present disclosure, a length of the side surface of the active layer close to the gate insulation layer extending beyond the edge of the gate insulation layer is greater than a length of the side surface of the gate insulation layer close to the gate electrode extending beyond the edge of the gate electrode.

According to the embodiments of the present disclosure, a material of the gate insulation layer includes silicon oxide, with a thickness of 0.1-0.2 μm; and a material of the gate electrode includes copper or aluminum, with a thickness of 0.4-0.6 μm.

According to the embodiments of the present disclosure, an included angle between a first side of the gate insulation layer close to the active layer and a side edge of the gate insulation layer is less than 90°.

According to the embodiments of the present disclosure, the display substrate further includes: a light shielding layer located on a side of the active layer in a direction perpendicular to the base substrate.

According to the embodiments of the present disclosure, an orthographic projection of the active layer on the base substrate falls within an orthographic projection of the light shielding layer on the base substrate.

According to the embodiments of the present disclosure, the display substrate further includes: a first insulation layer on a side of the light shielding layer away from the base substrate, the first insulation layer covers the light shielding layer.

According to the embodiments of the present disclosure, a material of the light shielding layer includes molybdenum or molybdenum-niobium alloy; and a material of the first insulation layer includes silicon oxide, with a thickness of 0.3-0.5 μm.

According to the embodiments of the present disclosure, a thickness of the light shielding layer is less than a thickness of the gate electrode.

According to the embodiments of the present disclosure, the display substrate further includes: a second insulation layer on a side of the gate electrode away from the base substrate; and a source electrode and a drain electrode on a side of the second insulation layer away from the base substrate, a material of the source electrode and the drain electrode includes copper or aluminum, with a thickness of 0.5-0.7 μm, respectively.

According to the embodiments of the present disclosure, the display substrate further includes: a passivation layer on a side of the source electrode and the drain electrode away from the base substrate, a material of the passivation layer includes silicon oxide or a combination of silicon oxide and silicon nitride, and a thickness of the passivation layer is less than a thickness of the second insulation layer.

According to the embodiments of the present disclosure, a portion of the side surface of the active layer close to the gate insulation layer extending beyond the edge of the gate insulation layer is conductorized; and the display substrate further includes: a first via hole and a second via hole communicated to the conductorized portion of the active layer, an orthographic projection of the first via hole on the base substrate and an orthographic projection of the second via hole on the base substrate are located on two sides of an orthographic projection of the gate electrode on the base substrate.

According to the embodiments of the present disclosure, the source electrode and the drain electrode are respectively connected to the conductorized portion of the active layer through the first via hole and the second via hole.

According to the embodiments of the present disclosure, the display substrate further includes: a third via hole communicated to the first insulation layer. an orthographic projection of the third via hole on the base substrate is spaced apart from the orthographic projection of the active layer on the base substrate.

According to the embodiments of the present disclosure, the display substrate further includes: a fourth via hole communicated to the light shielding layer, an orthographic projection of the fourth via hole on the base substrate overlaps with the orthographic projection of the third via hole on the base substrate; and the light shielding layer is connected to the source electrode or the drain electrode through the third via hole and the fourth via hole.

According to the embodiments of the present disclosure, the display substrate further includes: the fourth via hole, the first via hole and the second via hole are formed by one patterning process.

According to the embodiments of the present disclosure, the display substrate further includes: a material of the active layer includes IGZO.

In another aspect, a manufacturing method of a display substrate is provided, including: manufacturing a top-gate type thin film transistor on a side of a base substrate, the manufacturing the top-gate type thin film transistor on the side of the base substrate includes the following steps: forming an active layer, a gate insulation film layer, a gate film layer and a photoresist film layer sequentially on the base substrate; pre-baking the photoresist film layer; exposing the photoresist film layer to a light using a mask as a protection mask, and developing the exposed photoresist film layer without post-baking; over-etching the gate film layer to form a gate electrode using the developed photoresist film layer as a protection mask; over-etching the gate insulation film layer by a gaseous corrosion method to form a gate insulation layer using the developed photoresist film layer as a protection mask; peeling off the photoresist film layer remained on a surface of the gate electrode; and performing a conductive treatment to the active layer using the gate insulation layer as a protection mask.

According to the embodiments of the present disclosure, an edge of a side of the gate insulation layer close to the gate electrode exceeds an edge of the gate electrode, and an edge of a side of the active layer close to the gate insulation layer exceeds an edge of the gate insulation layer.

In yet another aspect, a display device is provided, including the display substrate as described above.

### BRIEF DESCRIPTION OF THE DRAWINGS

FIG. 1 is a flow chart of a manufacturing method of a display substrate according to an embodiment of the present disclosure;

FIG. 2 is a schematic view showing a manufacturing process of a display substrate according to an embodiment of the present disclosure; and

FIG. 3 is another schematic view showing a manufacturing process of a display substrate according to an embodiment of the present disclosure.

### DETAILED DESCRIPTION OF PREFERRED EMBODIMENTS

In order to make objectives, technical solutions, and advantages of the present disclosure clearer, embodiments of the present disclosure will be described in detail below.

A Thin Film Transistor (TFT) on a display substrate of an OLED display device may be classified into two types, i.e., top-gate type and bottom-gate type. The top-gate type TFT includes: a light shielding layer, a first insulation layer, an active layer, a gate insulation layer, a gate electrode, a second insulation layer, and a source and drain layer, which are sequentially disposed on a base substrate, and a source electrode is arranged opposite to a drain electrode in the source and drain layer. In a manufacturing process of a display substrate, after forming the gate electrode on the base substrate, the gate insulation layer needs to be partially etched so that the active layer under the gate insulation layer can be partially exposed, then the exposed portion of the active layer is subjected to a conductive treatment, and finally the source electrode and the drain electrode are connected to the treated active layer through via holes.

In the manufacturing process of the display substrate, it is difficult to form an ideal morphology of the gate insulation layer if it does not meet etching process requirements. For example, in case that an edge of a surface of the gate insulation layer close to the gate electrode in the TFT completely coincides with an edge of the gate electrode, after the active layer is subjected to a conductive treatment, a length of a channel region which is located under the gate insulation layer and is not subjected to the conductive treatment will become short, resulting in deterioration of the threshold voltage characteristic of the TFT and thereby affecting the product quality of the display device.

In order to improve the threshold voltage characteristic of the TFT and improve the product quality of the display device, embodiments of the present disclosure provide a manufacturing method of a display substrate, a display substrate, and a display device.

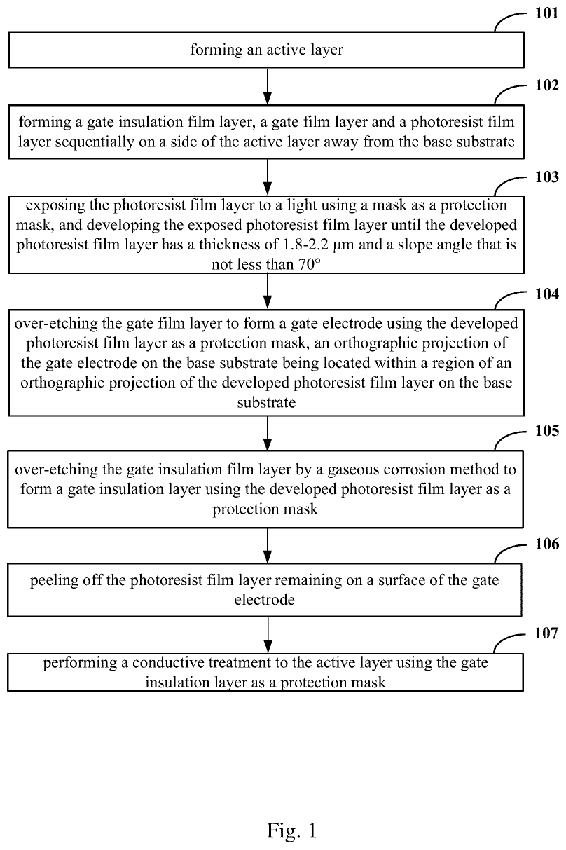

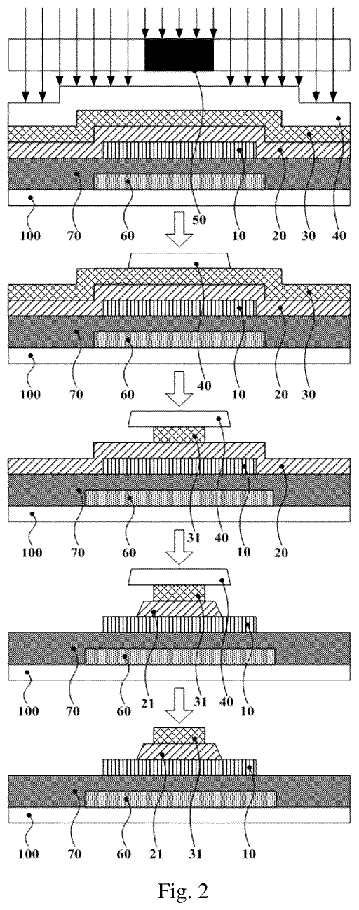

As shown in FIG. 1 and FIG. 2, a manufacturing method of a display substrate according to an embodiment of the present disclosure includes manufacturing a top-gate type thin film transistor on a side of a base substrate 100, the manufacturing the top-gate type thin film transistor on the side of the base substrate 100 includes the following steps:
forming an active layer 10;
forming a gate insulation film layer 20, a gate film layer 30 and a photoresist film layer 40 sequentially on a side of the active layer 10 away from the base substrate 100;
exposing the photoresist film layer 40 to a light using a mask 50 as a protection mask, so that a region of the photoresist film layer 40 corresponding to the gate electrode to be formed is not exposed, and a region corresponding to an etched region of the gate film layer 30 is fully exposed; the region of the photoresist film layer 40 corresponding to the gate electrode to be formed refers to a region directly above the gate electrode to be formed in the photoresist film layer 40, and the region of the photoresist film layer 40 corresponding to the etched region of the gate film layer 30 refers to a region directly above the etched region of the gate film layer 30 in the photoresist film layer 40;
developing the exposed photoresist film layer 40 until the developed photoresist film layer 40 has a thickness of 1.8-2.2 μm and a slope angle that is not less than 70°; the slope angle of the photoresist film layer may be defined as an included angle between a side surface and a bottom surface of the photoresist film layer;
over-etching (OE) the gate film layer 30 to form a gate electrode 31 using the developed photoresist film layer 40 as a protection mask, an orthographic projection of the gate electrode 31 on the base substrate 100 being located within a region of an orthographic projection of the developed photoresist film layer 40 on the base substrate 100; Over-etching may refer to an etching process in which the etching time is greater than a normal etching time, where the normal etching time refers to a time period that it takes for a film with a thickness of h to be etched to an etching depth of h;
over-etching the gate insulation film layer 20 for an over-etching time of (20%˜30%)*t by a gaseous corrosion method to form a gate insulation layer 21 using the developed photoresist film layer 40 as a protection mask; a gas atmosphere of the gaseous corrosion includes carbon tetrafluoride (CF₄) at a flow rate of 2000 to 2500 SCCM and oxygen (O₂) at a flow rate of 200 to 650 SCCM; where t is a normal time period during which the gate insulation film layer 20 is etched to a predetermined depth;
peeling off the photoresist film layer 40 remaining on a surface of the gate electrode; and
performing a conductive treatment to the active layer 10 using the gate insulation layer 21 as a protection mask.

Herein, SCCM is a unit of volumetric flow, which means milliliter per minute under a standard condition. The carbon tetrafluoride (CF₄) at the flow rate of 2000 to 2500 SCCM represents carbon tetrafluoride at a flow rate of 2000 to 2500 ml/min under the standard condition. The oxygen (O₂) at the flow rate of 200 to 650 SCCM represents oxygen at a flow rate of 200 to 650 ml/min under the standard condition. The specific material of the active layer 10 is not limited, and it may be selected from indium tin oxide (ITO) or IGZO with a thickness of 0.05 to 0.09 μm. The specific material of the gate insulation layer 21 is not limited, and it may be selected from a silicon oxide material with a thickness of 0.1 to 0.2 μm. The specific material of the gate electrode 31 is not limited, and it may be selected from copper or aluminum and other metal materials with a thickness of 0.4 to 0.6 μm. It should be noted that the gate film layer 30 may be etched by a wet etching method. When the gate film layer 30 is made from a copper material, the etching solvent may be hydrogen peroxide; when the gate film layer 30 is made from an aluminum material, the etching solvent may be mixed acid.

It should be noted that, before exposing the photoresist film layer 40 to the light, a pre-bake process is required. After the photoresist film layer 40 is exposed, a post-bake process is omitted and a development process is directly performed. In this way, it facilitates obtaining the photoresist film layer 40 with the above ideal thickness and slope angle. The purpose of over-etching the gate film layer 30 and the gate insulation film layer 20 is to prevent etching residue. When the thickness of the gate insulation film layer 20 is h, the normal time period during which the gate insulation film layer 20 is etched is a time period during which the etching depth reaches h.

A thin film transistor is formed on the base substrate 100 by using the manufacturing method provided by the embodiment of the present disclosure. By forming a photoresist film layer with a desired thickness and slope angle and by controlling the etching amount, a good morphology of the gate insulation layer 21 can be obtained without etching residue, thus the length of the channel region which is located under the gate insulation layer 21 will not be adversely affected when the active layer 10 is subsequently subjected to the conductive treatment, thereby improving the threshold voltage characteristic of the TFT and improving the product quality of the display device.

Optionally, an edge of the orthographic projection of the gate electrode 31 on the base substrate 100 is spaced apart from an edge of the orthographic projection of the developed photoresist film layer 40 on the base substrate 100 by 1 to 1.5 μm.

The designer of the present application has undergone a lot of experiments. According to the above manufacturing method, the orthographic projection of the gate insulation layer 21 on the base substrate 100 can be located within a region of the orthographic projection of the developed photoresist film layer 40 on the base substrate 100, and the edge of the side of the gate insulation layer 21 close to the gate electrode 31 exceeds the edge of the gate electrode 31, so that a good morphology of gate insulation layer 21 can be obtained and the length of the channel region which is located under the gate insulation layer 21 will not be adversely affected, thereby improving the threshold voltage characteristic of the TFT.

In an embodiment of the present disclosure, before the step of forming the active layer 10, the manufacturing method further includes:
forming a light shielding layer 60 on the base substrate, the active layer 10 being opposite to the light shielding layer 60; and
forming a first insulation layer 70 covering the light shielding layer 60 on a side of the light shielding layer 60 away from the base substrate 100.

The specific material of the light shielding layer 60 is not limited, and it may be selected from a metal material such as molybdenum or molybdenum-niobium alloy, with a thickness of 0.15 μm. The specific material of the first insulation layer 70 is not limited, and it may be selected from a silicon oxide material with a thickness of 0.3 to 0.5 μm.

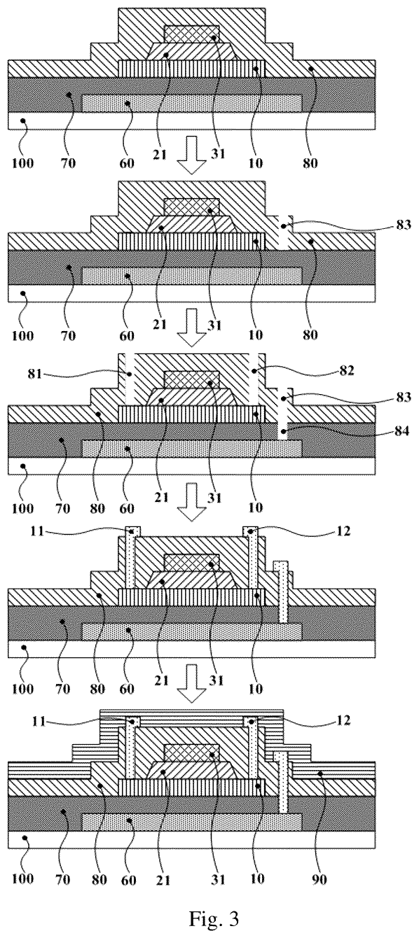

As shown in FIG. 3, in an embodiment of the present disclosure, the manufacturing method of the display substrate further includes:
forming a second insulation layer 80 on a side of the gate electrode 31 away from the base substrate 100;
forming a first via hole 81 and a second via hole 82 communicated to the active layer 10 which has been performed by the conductive treatment, orthographic projections of the first via hole 81 and the second via hole 82 on the base substrate 100 are respectively located at two sides of an orthographic projection of the gate electrode 31 on the base substrate 100;
forming a source electrode 11 and a drain electrode 12 on a side of the second insulation layer 80 away from the base substrate 100, the source electrode 11 and the drain electrode 12 being connected to the active layer 10 which has been performed by the conductive treatment respectively through the first via hole 81 and the second via hole 82.

The specific material of the second insulation layer 80 is not limited, and it may be selected from a silicon oxide material with a thickness of 0.3 to 0.5 μm. The specific materials of the source electrode 11 and the drain electrode 12 are not limited, and they may be selected from copper or aluminum and other metal materials with a thickness of 0.5 to 0.7 μm.

Further referring to FIG. 3, in an embodiment of the present disclosure, the manufacturing method of the display substrate further includes:

forming a third via hole 83 communicated to the first insulation layer 70, an orthographic projection of the third via hole 83 on the base substrate 100 is spaced apart from an orthographic projection of the active layer 10 on the base substrate 100;

forming a fourth via hole 84 communicated to the light shielding layer 60, an orthographic projection of the fourth via hole 84 on the base substrate 100 coinciding with the orthographic projection of the third via hole 83 on the base substrate 100, and the light shielding layer 60 being connected to the source electrode 11 or the drain electrode 12 through the fourth via hole 84 and the third via hole 83.

The light shielding layer 60 is generally made of metal, thus in the solution according to this embodiment, by connecting the light shielding layer 60 with the source electrode 11 or the drain electrode 12, cross-over resistance between the layers is reduced, thereby improving the performance of the TFT.

In an embodiment, the fourth via hole 84, the first via hole 81 and the second via hole 82 are formed by one patterning process. That is to say, after the second insulation layer 80 is formed on the side of the gate electrode 31 away from the base substrate 100, the third via hole 83 communicated to the first insulation layer 70 is formed by one patterning process, and then the fourth via hole 84, the first via hole 81 and the second via hole 82 are simultaneously formed by one patterning process, which can greatly simplify the manufacturing process of the display substrate.

In an embodiment, after forming the source electrode 11 and the drain electrode 12 on the side of the second insulation layer 80 away from the base substrate 100, the manufacturing method further includes:

forming a passivation layer 90 on a side of the source electrode 11 and the drain electrode 12 away from the base substrate 100.

The specific material of the passivation layer 90 is not limited, and it may be selected from silicon oxide, a combination of silicon oxide and silicon nitride, with a thickness of 0.3 to 0.4 μm.

An embodiment of the present disclosure also provides a display substrate manufactured by the manufacturing method of the display substrate according to any one of the foregoing technical solutions. The threshold voltage characteristic of the TFT of the display substrate is improved.

An embodiment of the present disclosure also provides a display device including the display substrate according to any one of the foregoing technical solutions. Since the threshold voltage characteristic of the TFT of the display substrate is improved, the display device also has better product quality. The specific product type of the display device is not limited, and it may be, for example, a display, a display screen, a flat panel TV, or the like.

It will be apparent to those skilled in the art that various modifications and variations can be made to the embodiments of the present disclosure without departing from the spirit and scope of the present disclosure. Thus, if these modifications and variations to the present disclosure fall within the scope of the claims of the present disclosure and equivalent thereof, the present disclosure is also intended to include these modifications and variations.

What is claimed is:

1. A display substrate, comprising:
a base substrate; and
a top-gate type thin film transistor located on a side of the base substrate, wherein the top-gate type thin film transistor comprises an active layer, a gate insulation layer and a gate electrode sequentially disposed in a direction away from the base substrate,
wherein a side surface of the gate insulation layer close to the gate electrode extends beyond an edge of the gate electrode in a direction parallel to the base substrate, and a side surface of the active layer close to the gate insulation layer extends beyond an edge of the gate insulation layer in the direction parallel to the base substrate.

2. The display substrate according to claim 1, wherein a length of the side surface of the active layer close to the gate insulation layer extending beyond the edge of the gate insulation layer is greater than a length of the side surface of the gate insulation layer close to the gate electrode extending beyond the edge of the gate electrode.

3. The display substrate according to claim 1, wherein a material of the gate insulation layer comprises silicon oxide, with a thickness of 0.1-0.2 μm; and
wherein a material of the gate electrode comprises copper or aluminum, with a thickness of 0.4-0.6 μm.

4. The display substrate according to claim 1, wherein an included angle between a first side of the gate insulation layer close to the active layer and a side edge of the gate insulation layer is less than 90°.

5. The display substrate according to claim 1, further comprising:
a light shielding layer located on a side of the active layer in a direction perpendicular to the base substrate.

6. The display substrate according to claim 5, wherein an orthographic projection of the active layer on the base substrate falls within an orthographic projection of the light shielding layer on the base substrate.

7. The display substrate according to claim 5, further comprising:
a first insulation layer on a side of the light shielding layer away from the base substrate, wherein the first insulation layer covers the light shielding layer.

8. The display substrate according to claim 5, wherein a material of the light shielding layer comprises molybdenum or molybdenum-niobium alloy; and
wherein a material of the first insulation layer comprises silicon oxide, with a thickness of 0.3-0.5 μm.

9. The display substrate according to claim 5, wherein a thickness of the light shielding layer is less than a thickness of the gate electrode.

10. The display substrate according to claim 1, further comprising:
a second insulation layer on a side of the gate electrode away from the base substrate; and
a source electrode and a drain electrode on a side of the second insulation layer away from the base substrate, and a material of the source electrode and the drain electrode comprises copper or aluminum, with a thickness of 0.5-0.7 μm,
respectively.

11. The display substrate according to claim 10, further comprising:
a passivation layer on a side of the source electrode and the drain electrode away from the base substrate, wherein a material of the passivation layer comprises silicon oxide or a combination of silicon oxide and silicon nitride, and a thickness of the passivation layer is less than a thickness of the second insulation layer.

12. The display substrate according to claim 1,
wherein a portion of the side surface of the active layer close to the gate insulation layer extending beyond the edge of the gate insulation layer is conductorized; and
wherein the display substrate further comprises: a first via hole and a second via hole communicated to the conductorized portion of the active layer, wherein an orthographic projection of the first via hole on the base substrate and an orthographic projection of the second via hole on the base substrate are located on two sides of an orthographic projection of the gate electrode on the base substrate.

13. The display substrate according to claim 12, wherein the source electrode and the drain electrode are respectively connected to the conductorized portion of the active layer through the first via hole and the second via hole.

14. The display substrate according to claim 12, further comprising:
a third via hole communicated to the first insulation layer, wherein an orthographic projection of the third via hole on the base substrate is spaced apart from the orthographic projection of the active layer on the base substrate.

15. The display substrate according to claim 14, further comprising:
a fourth via hole communicated to the light shielding layer, wherein an orthographic projection of the fourth via hole on the base substrate overlaps with the orthographic projection of the third via hole on the base substrate; and
wherein the light shielding layer is connected to the source electrode or the drain electrode through the third via hole and the fourth via hole.

16. The display substrate according to claim 15, wherein the fourth via hole, the first via hole and the second via hole are formed by one patterning process.

17. The display substrate according to claim 1, wherein a material of the active layer comprises IGZO.

18. A manufacturing method of a display substrate, comprising manufacturing a top-gate type thin film transistor on a side of a base substrate, wherein the manufacturing the top-gate type thin film transistor on the side of the base substrate comprises the following steps:
forming an active layer, a gate insulation film layer, a gate film layer and a photoresist film layer sequentially on the base substrate;
pre-baking the photoresist film layer;
exposing the photoresist film layer to a light using a mask as a protection mask, and developing the exposed photoresist film layer without post-baking;
over-etching the gate film layer to form a gate electrode using the developed photoresist film layer as a protection mask;
over-etching the gate insulation film layer by a gaseous corrosion method to form a gate insulation layer using the developed photoresist film layer as a protection mask;
peeling off the photoresist film layer remained on a surface of the gate electrode; and
performing a conductive treatment to the active layer using the gate insulation layer as a protection mask.

19. The method according to claim 18, wherein an edge of a side of the gate insulation layer close to the gate electrode exceeds an edge of the gate electrode, and an edge of a side of the active layer close to the gate insulation layer exceeds an edge of the gate insulation layer.

20. A display device, comprising the display substrate according to claim 1.
